(19) United States
(12) Patent Application Publication
(10) Pub. No.: US 2026/0157169 A1
(43) Pub. Date: Jun. 4, 2026

(54) CONDUCTIVE BLACK METALS FOR MIXED REALITY LIQUID CRYSTAL DISPLAY DEVICE

(71) Applicant: Meta Platforms Technologies, LLC, Menlo Park, CA (US)

(72) Inventors: Cagdas Varel, Seattle, WA (US); Rungrot Kitsomboonloha, Los Gatos, CA (US); Hsin-Ying Chiu, San Jose, CA (US); Yun-Han Lee, Redmond, WA (US); Wan-Yu Lin, Taipei City (TW)

(21) Appl. No.: 19/181,989

(22) Filed: Apr. 17, 2025

Related U.S. Application Data
(60) Provisional application No. 63/635,579, filed on Apr. 17, 2024.

(51) Int. Cl. H10W 20/44; H10D 86/40; H10W 20/00; H10W 20/41

(52) U.S. Cl. CPC H10W 20/4441; H10D 86/441; H10W 20/031; H10W 20/438

(57) ABSTRACT

Structures for black metal and related methods are described. In some implementations, a black metal structure may include: a first molybdenum layer deposited on a substrate, an indium tin oxide (ITO) layer deposited on the first molybdenum layer, a second molybdenum layer deposited on the ITO layer, and a second ITO layer deposited on the second molybdenum layer.

### CROSS REFERENCE TO RELATED APPLICATIONS

This present application claims the benefit of priority under 35 U.S.C. § 119(e) to U.S. Provisional Application No. 63/635,579, filed Apr. 17, 2024, the disclosure of which is hereby incorporated by reference in its entirety for all purposes.

### TECHNICAL FIELD

The present disclosure generally relates to display technologies, and more particularly to conductive metals for mixed reality liquid crystal display devices.

### BACKGROUND

Liquid crystal display (LCD) technology is widely used in various applications, including mixed reality (MR) devices, due to its ability to produce high-resolution images. In these displays, black metal layers may be employed to reduce off-axis color mixing and act as light-shielding layers for underlying metal routing lines. These black metal layers may be created using a silicon nitride (SiNx) and molybdenum (Mo) layer stack, deposited through a chemical vapor deposition (CVD) process. The CVD process may require multiple masks and precise alignment to ensure proper layer deposition.

### BRIEF SUMMARY

The subject disclosure provides for improved display technologies and related methods. For example, the disclosed display technologies and related methods enable the reduction of reflectance in high pixel-per-inch (PPI) liquid crystal displays (LCDs) used in mixed reality (MR) devices, such as virtual reality (VR) and augmented reality (AR) headsets. By replacing traditional chemical vapor deposition (CVD) processes with physical vapor deposition (PVD) processes and incorporating conductive materials like indium tin oxide (ITO) into the black metal layer stack, the disclosed technology minimizes manufacturing inefficiencies, reduces misalignment errors, and improves display performance. A user benefits from enhanced visual clarity and reduced ghosting effects, resulting in a more immersive and seamless MR experience.

One aspect of the disclosure relates to a black metal structure. The structure may include a first molybdenum layer deposited on a substrate. The structure may include an indium tin oxide (ITO) layer deposited on the first molybdenum layer. The structure may include a second molybdenum layer deposited on the ITO layer. The structure may include a second ITO layer deposited on the second molybdenum layer.

Another aspect of the disclosure relates to an alternate embodiment of the black metal structure. The structure may include a metal layer deposited on a substrate. The structure may include a first conductive and transparent material layer deposited on the metal layer. The structure may include a second conductive and transparent material layer deposited on the first conductive and transparent material layer. The structure may include a third conductive and transparent material layer deposited on the second conductive and transparent material layer.

Yet another aspect of the disclosure relates to a method of manufacturing a black metal structure. The method may include depositing a first molybdenum layer on a substrate. The method may include depositing an ITO layer on the first molybdenum layer. The method may include depositing a second molybdenum layer on the ITO layer. The method may include depositing a second ITO layer on the second molybdenum layer.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a block diagram illustrating an overview of devices on which some implementations of the disclosed technology can operate.

FIG. 2A is a wire diagram of a virtual reality head-mounted display (HMD), in accordance with one or more implementations.

FIG. 2B is a wire diagram of a mixed reality HMD system which includes a mixed reality HMD and a core processing component, in accordance with one or more implementations.

FIG. 3 is a block diagram illustrating an overview of an environment, in which some implementations of the disclosed technology can operate.

FIG. 4 illustrates a layer stack diagram which supports techniques for conductive metals for mixed reality liquid crystal display devices, in accordance with various aspects of the present disclosure.

FIG. 5 illustrates a misalignment which supports techniques for conductive metals for mixed reality liquid crystal display devices, in accordance with various aspects of the present disclosure.

FIG. 6 illustrates silicon nitride loss which supports techniques for conductive metals for mixed reality liquid crystal display devices, in accordance with various aspects of the present disclosure.

FIGS. 7A and 7B show line graphs illustrating the optimized (minimized) transmission and reflectivity at different angles of incidence across a range of wavelengths, in accordance with various aspects of the present disclosure.

FIG. 8 illustrates a layer stack comparison which supports techniques for conductive metals for mixed reality liquid crystal display devices, in accordance with various aspects of the present disclosure.

FIG. 9 illustrates a layer structure comparison which supports techniques for conductive metals for mixed reality liquid crystal display devices, in accordance with various aspects of the present disclosure.

FIG. 10 illustrates a generalized layer structure which supports techniques for conductive metals for mixed reality liquid crystal display devices, in accordance with various aspects of the present disclosure.

FIG. 11 illustrates a flowchart illustrating a method of manufacturing structures, in accordance with various aspects of the present disclosure.

FIG. 12 illustrates a flowchart illustrating a method of manufacturing alternate structures, in accordance with various aspects of the present disclosure.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

In the following detailed description, numerous specific details are set forth to provide a full understanding of the present disclosure. It will be apparent, however, to one ordinarily skilled in the art, that the embodiments of the present disclosure may be practiced without some of these specific details. In other instances, well-known structures and techniques have not been shown in detail so as not to obscure the disclosure.

In one aspect, unless otherwise stated, all measurements, values, ratings, positions, magnitudes, sizes, and other specifications that are set forth in this specification, including in the clauses that follow, are approximate, not exact. In one aspect, they are intended to have a reasonable range (e.g., +/−10%) that is consistent with the functions to which they relate and with what is customary in the art to which they pertain. It is understood that some or all steps, operations, or processes may be performed automatically, without the intervention of a user. Method clauses may be provided to present elements of the various steps, operations, or processes in a sample order, and are not meant to be limited to the specific order or hierarchy presented.

Embodiments of the disclosed technology may include or be implemented in conjunction with a mixed reality system. The term “mixed reality” or “MR” as used herein refers to a form of reality that has been adjusted in some manner before presentation to a user, which may include, e.g., virtual reality (VR), augmented reality (AR), extended reality (XR), hybrid reality, or some combination and/or derivatives thereof. Mixed reality content may include completely generated content or generated content combined with captured content (e.g., real-world photographs). The mixed reality content may include video, audio, haptic feedback, or some combination thereof, any of which may be presented in a single channel or in multiple channels (such as stereo video that produces a three-dimensional (3D) effect to the viewer). Additionally, in some embodiments, mixed reality may be associated with applications, products, accessories, services, or some combination thereof, that are, e.g., used to interact with content in an immersive application. The mixed reality system that provides the mixed reality content may be implemented on various platforms, including a head-mounted display (HMD) connected to a server, a host computer system, a standalone HMD, a mobile device or computing system, a “cave” environment or other projection system, or any other hardware platform capable of providing mixed reality content to one or more viewers. Mixed reality may be equivalently referred to herein as “artificial reality.”

“Virtual reality” or “VR,” as used herein, refers to an immersive experience where a user's visual input is controlled by a computing system. “Augmented reality” or “AR” as used herein refers to systems where a user views images of the real world after they have passed through a computing system. For example, a tablet with a camera on the back can capture images of the real world and then display the images on the screen on the opposite side of the tablet from the camera. The tablet can process and adjust or “augment” the images as they pass through the system, such as by adding virtual objects. AR also refers to systems where light entering a user's eye is partially generated by a computing system and partially composes light reflected off objects in the real world. For example, an AR headset could be shaped as a pair of glasses with a pass-through display, which allows light from the real world to pass through a waveguide that simultaneously emits light from a projector in the AR headset, allowing the AR headset to present virtual objects intermixed with the real objects the user can see. The AR headset may be a block-light headset with video pass-through. “Mixed reality” or “MR,” as used herein, refers to any of VR, AR, XR, or any combination or hybrid thereof.

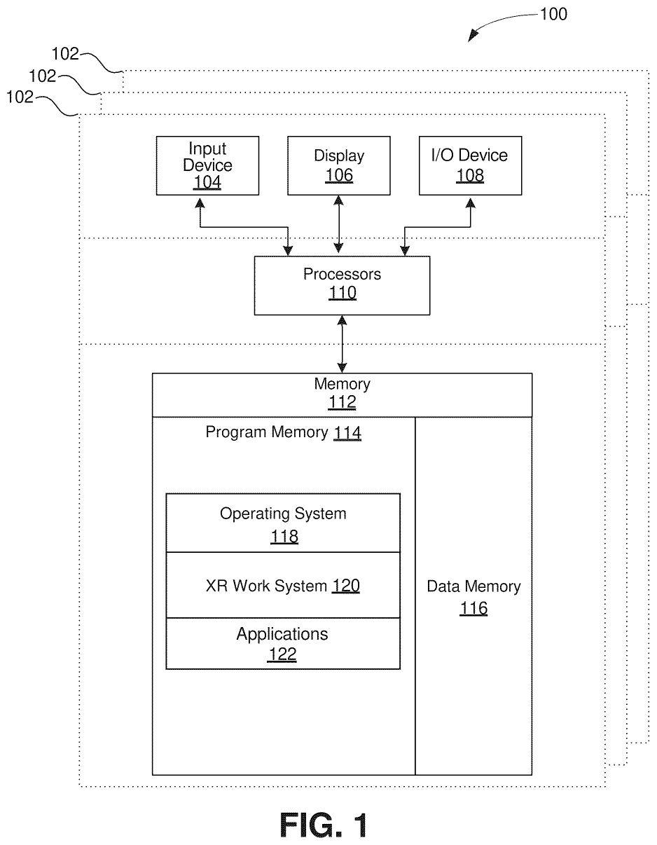

Several implementations are discussed below in more detail in reference to the figures. FIG. 1 is a block diagram of a device operating environment 100 with which aspects of the subject technology can be implemented. The device operating environment can comprise hardware components of a computing system 100 that can create, administer, and provide interaction modes for a shared artificial reality environment (e.g., gaming artificial reality environment) such as for individual control of audio (e.g., switching audio sources) via XR elements and/or real-world audio elements. The interaction modes can include different audio sources or channels for each user of the computing system 100. Some of these audio channels may be spatialized or non-spatialized. In various implementations, the computing system 100 can include a single computing device or multiple computing devices 102 that communicate over wired or wireless channels to distribute processing and share input data.

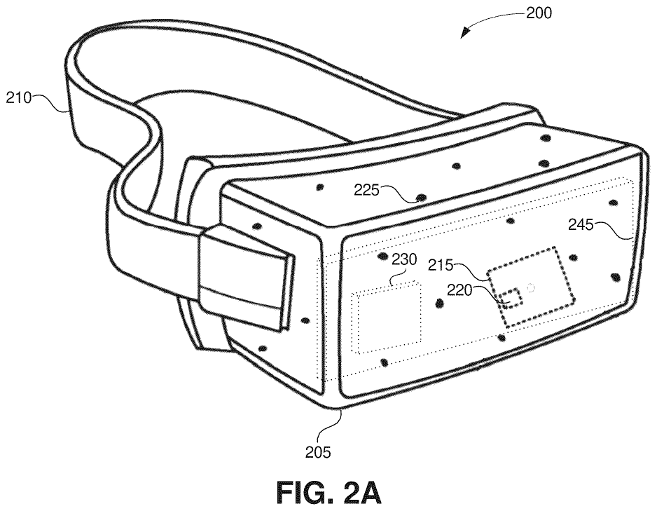

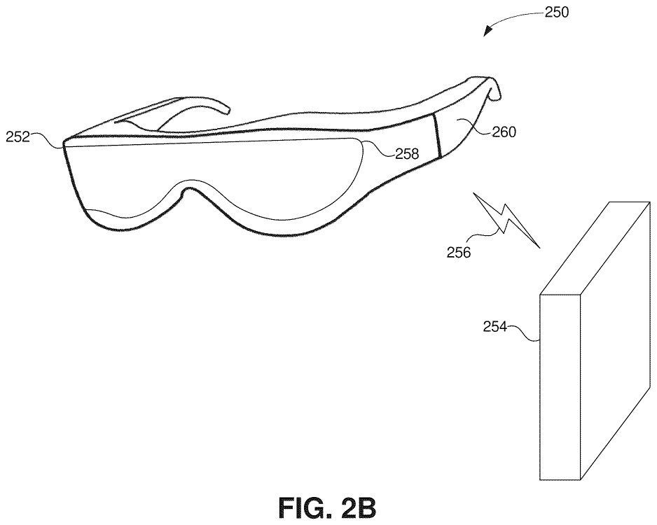

In some implementations, the computing system 100 can include a stand-alone headset capable of providing a computer created or augmented experience for a user without the need for external processing or sensors. In other implementations, the computing system 100 can include multiple computing devices 102 such as a headset and a core processing component (such as a console, mobile device, or server system) where some processing operations are performed on the headset and others are offloaded to the core processing component. Example headsets are described below in relation to FIGS. 2A-2B. In some implementations, position and environment data can be gathered only by sensors incorporated in the headset device, while in other implementations one or more of the non-headset computing devices 102 can include sensor components that can track environment or position data, such as for implementing computer vision functionality. Additionally or alternatively, such sensors can be incorporated as wrist sensors, which can function as a wrist wearable for detecting or determining user input gestures. For example, the sensors may include inertial measurement units (IMUs), eye tracking sensors, electromyography (e.g., for translating neuromuscular signals to specific gestures), time of flight sensors, light/optical sensors, and/or the like to determine the input gestures, how user hands/wrists are moving, and/or environment and position data.

The computing system 100 can include one or more processor(s) 110 (e.g., central processing units (CPUs), graphical processing units (GPUs), holographic processing units (HPUs), etc.). The processors 110 can be a single processing unit or multiple processing units in a device or distributed across multiple devices (e.g., distributed across two or more of computing devices 102). The computing system 100 can include one or more input devices 104 that provide input to the processors 110, notifying them of actions. The actions can be mediated by a hardware controller that interprets the signals received from the input device 104 and communicates the information to the processors 110 using a communication protocol. As an example, the hardware controller can translate signals from the input device 104 to render audio, motion, or other signal-controlled features in the shared XR environment. Each input device 104 can include, for example, a mouse, a keyboard, a touchscreen, a touchpad, a wearable input device (e.g., a haptics glove, a bracelet, a ring, an earring, a necklace, a watch, etc.), a camera (or other light-based input device, e.g., an infrared sensor), a microphone, and/or other user input devices.

The processors 110 can be coupled to other hardware devices, for example, with the use of an internal or external bus, such as a PCI bus, SCSI bus, wireless connection, and/or the like. The processors 110 can communicate with a hardware controller for devices, such as for a display 106. The display 106 can be used to display text and graphics. In some implementations, the display 106 includes the input device as part of the display, such as when the input device is a touchscreen or is equipped with an eye direction monitoring system. In some implementations, the display is separate from the input device. Examples of display devices include an LCD display screen, an LED display screen, a projected, holographic, or augmented reality display (such as a heads-up display device or a head-mounted device), and/or the like. Other I/O devices 108 can also be coupled to the processor, such as a network chip or card, video chip or card, audio chip or card, USB, firewire or other external device, camera, printer, speakers, CD-ROM drive, DVD drive, disk drive, etc.

The computing system 100 can include a communication device capable of communicating wirelessly or wire-based with other local computing devices 102 or a network node. The communication device can communicate with another device or a server through a network using, for example, TCP/IP protocols. The computing system 100 can utilize the communication device to distribute operations across multiple network devices. For example, the communication device can function as a communication module. The communication device can be configured to transmit or receive audio signals.

The processors 110 can have access to a memory 112, which can be contained on one of the computing devices 102 of the computing system 100 or can be distributed across one of the multiple computing devices 102 of the computing system 100 or other external devices. A memory includes one or more hardware devices for volatile or non-volatile storage, and can include both read-only and writable memory. For example, a memory can include one or more of random access memory (RAM), various caches, CPU registers, read-only memory (ROM), and writable non-volatile memory, such as flash memory, hard drives, floppy disks, CDs, DVDs, magnetic storage devices, tape drives, and so forth. A memory is not a propagating signal divorced from underlying hardware; a memory is thus non-transitory. The memory 112 can include program memory 114 that stores programs and software, such as an operating system 118, XR work system 120, and other application programs 122 (e.g., XR games). The memory 112 can also include data memory 116 that can include information to be provided to the program memory 114 or any element of the computing system 100.

Some implementations can be operational with numerous other computing system environments or configurations. Examples of computing systems, environments, and/or configurations that may be suitable for use with the technology include, but are not limited to, XR headsets, personal computers, server computers, handheld or laptop devices, cellular telephones, wearable electronics, gaming consoles, tablet devices, multiprocessor systems, microprocessor-based systems, set-top boxes, programmable consumer electronics, network PCs, minicomputers, mainframe computers, distributed computing environments that include any of the above systems or devices, and/or the like.

FIGS. 2A-2B are diagrams illustrating virtual reality headsets, according to certain aspects of the present disclosure. FIG. 2A is a diagram of a virtual reality head-mounted display (HMD) 200. The HMD 200 includes a front rigid body 205 and a band 210. The front rigid body 205 includes one or more electronic display elements such as an electronic display 245, an inertial motion unit (IMU) 215, one or more position sensors 220, locators 225, and one or more compute units 230. The position sensors 220, the IMU 215, and compute units 230 may be internal to the HMD 200 and may not be visible to the user. In various implementations, the IMU 215, position sensors 220, and locators 225 can track movement and location of the HMD 200 in the real world and in a virtual environment in three degrees of freedom (3DoF), six degrees of freedom (6DoF), etc. For example, the locators 225 can emit infrared light beams which create light points on real objects around the HMD 200. As another example, the IMU 215 can include, e.g., one or more accelerometers, gyroscopes, magnetometers, other non-camera-based position, force, or orientation sensors, or combinations thereof. One or more cameras (not shown) integrated with the HMD 200 can detect the light points, such as for a computer vision algorithm or module. The compute units 230 in the HMD 200 can use the detected light points to extrapolate position and movement of the HMD 200 as well as to identify the shape and position of the real objects surrounding the HMD 200.

The electronic display 245 can be integrated with the front rigid body 205 and can provide image light to a user as dictated by the compute units 230. In various embodiments, the electronic display 245 can be a single electronic display or multiple electronic displays (e.g., a display for each user eye). Examples of the electronic display 245 include: a liquid crystal display (LCD), an organic light-emitting diode (OLED) display, an active-matrix organic light-emitting diode display (AMOLED), a display including one or more quantum dot light-emitting diode (QOLED) sub-pixels, a projector unit (e.g., microLED, LASER, etc.), some other display, or some combination thereof. The electronic display 245 can be coupled with an audio component, such as to send and receive output from various other users of the XR environment wearing their own XR headsets, for example. The audio component can be configured to host multiple audio channels, sources, or modes.

In some implementations, the HMD 200 can be coupled to a core processing component such as a personal computer (PC) (not shown) and/or one or more external sensors (not shown). The external sensors can monitor the HMD 200 (e.g., via light emitted from the HMD 200) which the PC can use, in combination with output from the IMU 215 and position sensors 220, to determine the location and movement of the HMD 200.

FIG. 2B is a diagram of a mixed reality HMD system 250 which includes a mixed reality HMD 252 and a core processing component 254. The mixed reality HMD 252 and the core processing component 254 can communicate via a wireless connection (e.g., a 60 GHz link) as indicated by the link 256. In other implementations, the mixed reality system 250 includes a headset only, without an external compute device or includes other wired or wireless connections between the mixed reality HMD 252 and the core processing component 254. The mixed reality HMD 252 includes a pass-through display 258 and a frame 260. The frame 260 can house various electronic components (not shown), such as light projectors (e.g., LASERs, LEDs, etc.), cameras, eye-tracking sensors, MEMS components, networking components, etc. The frame 260 or another part of the mixed reality HMD 252 may include an audio electronic component such as a speaker. The speaker can output audio from various audio sources, such as a phone call, VoIP session, or other audio channel. The electronic components may be configured to implement audio switching based on user gaming or XR interactions.

The projectors can be coupled to the pass-through display 258, e.g., via optical elements, to display media to a user. The optical elements can include one or more waveguide assemblies, reflectors, lenses, mirrors, collimators, gratings, etc., for directing light from the projectors to a user's eye. Image data can be transmitted from the core processing component 254 via link 256 to HMD 252. Controllers in the HMD 252 can convert the image data into light pulses from the projectors, which can be transmitted via the optical elements as output light to the user's eye. The output light can mix with light that passes through the display 258, allowing the output light to present virtual objects that appear as if they exist in the real world.

Similarly to the HMD 200, the HMD system 250 can also include motion and position tracking units, cameras, light sources, etc., which allow the HMD system 250 to, e.g., track itself in 3DoF or 6DoF, track portions of the user (e.g., hands, feet, head, or other body parts), map virtual objects to appear as stationary as the HMD 252 moves, and have virtual objects react to gestures and other real-world objects. For example, the HMD system 250 can track the motion and position of user's wrist movements as input gestures for performing XR navigation. As an example, the HMD system 250 may include a coordinate system to track the relative positions of various XR objects and elements in a shared artificial reality environment.

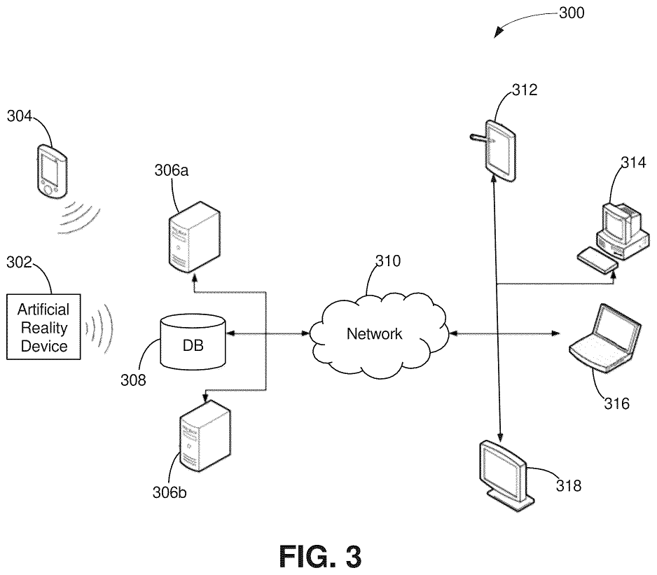

FIG. 3 is a block diagram illustrating an overview of an environment 300 in which some implementations of the disclosed technology can operate. The environment 300 can include one or more client computing devices, such as artificial reality device 302, mobile device 304, tablet 312, personal computer 314, laptop 316, desktop 318, and/or the like. The artificial reality device 302 may be the HMD 200, HMD system 250, a wrist wearable, or some other XR device that is compatible with rendering or interacting with an artificial reality or virtual reality environment. The artificial reality device 302 and mobile device 304 may communicate wirelessly via the network 310. In some implementations, some of the client computing devices can be the HMD 200 or the HMD system 250. The client computing devices can operate in a networked environment using logical connections through network 310 to one or more remote computers, such as a server computing device.

In some implementations, the environment 300 may include a server such as an edge server which receives client requests and coordinates fulfillment of those requests through other servers. The server may include server computing devices 306a-306b, which may logically form a single server. Alternatively, the server computing devices 306a-306b may each be a distributed computing environment encompassing multiple computing devices located at the same or at geographically disparate physical locations. The client computing devices and server computing devices 306a-306b can each act as a server or client to other server/client device(s).

The server computing devices 306a-306b can connect to a database 308 or can comprise its own memory. Each server computing devices 306a-306b can correspond to a group of servers, and each of these servers can share a database or can have their own database. The database 308 may logically form a single unit or may be part of a distributed computing environment encompassing multiple computing devices that are located within their corresponding server, located at the same or at geographically disparate physical locations.

The network 310 can be a local area network (LAN), a wide area network (WAN), a mesh network, a hybrid network, or other wired or wireless networks. The network 310 may be the Internet or some other public or private network. Client computing devices can be connected to network 310 through a network interface, such as by wired or wireless communication. The connections can be any kind of local, wide area, wired, or wireless network, including the network 310 or a separate public or private network. In some implementations, the server computing devices 306a-306b can be used as part of a social network such as implemented via the network 310. The social network can maintain a social graph and perform various actions based on the social graph. A social graph can include a set of nodes (representing social networking system objects, also known as social objects) interconnected by edges (representing interactions, activity, or relatedness). A social networking system object can be a social networking system user, nonperson entity, content item, group, social networking system page, location, application, subject, concept representation or other social networking system object, e.g., a movie, a band, a book, etc.

In some examples, the method of using a chemical vapor deposition process to deposit black metal layers in liquid crystal display panels may present several challenges. The requirement for multiple masks may increase the complexity and cost of the manufacturing process. Misalignment errors due to the use of three masks may lead to non-uniformity in the layers, affecting the electrical and optical performance of the display. Additionally, the chemical vapor deposition process may cause arcing, which may necessitate the patterning of metal layers before successive layers can be deposited. This patterning process may exacerbate issues such as increased common electrode resistance and difficulties in achieving uniform coverage of the liquid crystal alignment layer, polyimide.

The subject disclosure provides for improved display technologies and related methods. For example, the disclosed display technologies and related methods enable the reduction of reflectance in high pixel-per-inch (PPI) liquid crystal displays (LCDs) used in mixed reality (MR) devices, such as virtual reality (VR) and augmented reality (AR) headsets. By replacing traditional chemical vapor deposition (CVD) processes with physical vapor deposition (PVD) processes and incorporating conductive materials like indium tin oxide (ITO) into the black metal layer stack, the disclosed technology minimizes manufacturing inefficiencies, reduces misalignment errors, and improves display performance. A user benefits from enhanced visual clarity and reduced ghosting effects, resulting in a more immersive and seamless MR experience.

Implementations described herein address the aforementioned shortcomings and other shortcomings by replacing the chemical vapor deposition (CVD) process with a physical vapor deposition (PVD) process, utilizing materials such as indium tin oxide (ITO) instead of silicon nitride (SiNx). The PVD process, such as sputtering, may eliminate the need for multiple masks and prevent issues related to arcing and misalignment during the deposition of black metal layers. By using ITO, which has a similar refractive index to SiNx (e.g., Both ITO and SiNx has refractive index around 1.8-2) and may be deposited through PVD, some implementations ensure that the black metal layers maintain their low reflectivity and light-shielding properties without the drawbacks associated with the CVD process.

Furthermore, the use of ITO in the PVD process may provide additional benefits, such as improved etch selectivity and electrical conductivity. This approach may simplify the fabrication process, reduce manufacturing costs, and enhance the overall performance and reliability of high pixel per inch (PPI) virtual reality (VR) liquid crystal display (LCD) panels. Some implementations represent a significant advancement in the production of LCD panels for VR devices, offering a more efficient and cost-effective solution for achieving high-quality displays.

According to some implementations, the chemical vapor deposition (CVD) process may be replaced with a physical vapor deposition (PVD) process, such as sputtering. This may eliminate the need for multiple masks typically required in the CVD process and may mitigate issues related to electrical arcing that occur during the deposition of black metal layers in the CVD process.

In some implementations, indium tin oxide (ITO) may be used instead of silicon nitride (SiNx) in the black metal layer stack. ITO may have a similar refractive index to SiNx, allowing it to replace SiNx without significant changes to the black metal thickness. ITO may be deposited using the PVD process, eliminating the need for CVD. ITO may serve as an etch stopper for molybdenum (Mo) layers during the etching process and may exhibit good etch selectivity against SiNx used in the pixel operation layer. Additionally, ITO may have good electrical conductivity, making it suitable for use in the black metal layer stack.

Some implementations may eliminate the need for a three-mask process, which is typically required in the CVD-based approach to prevent arcing. The three-mask process may involve patterning the first (bottom) Mo layer, patterning the second Mo layer, and patterning the black metal stack (four layers) to the final structure. By using the PVD process and ITO, some implementations may reduce the process to a single mask, simplifying fabrication and reducing costs.

Some implementations may reduce misalignment errors caused by the use of multiple masks in the CVD process. Misalignment in the three-mask process may lead to variations in the size of non-uniform areas in the pixel operation layer. Large misalignments may reduce the anti-reflective effectiveness of the black metal and increase display reflectance.

The PVD process may eliminate the arcing issues associated with the CVD process. Arcing in CVD may occur due to the need to pattern Mo layers before successive layers are deposited.

The PVD process may simplify the fabrication process by reducing the number of lithography and etching steps. The simplified process may reduce takt time and overall manufacturing costs.

Some implementations may prevent the loss of the SiNx layer underneath the black metal layer stack. In the CVD process, etchants used for SiNx and/or Mo layers may cause complete or partial loss of the underlying SiNx layer, leading to non-uniform electrical and optical performance. ITO, used in the PVD process, may act as an etch stopper, preventing the over-etching of the SiNx layer.

Some implementations may ensure uniformity in the pixel operation layer, leading to consistent electrical and optical performance. Some implementations may avoid the formation of black pixels caused by the loss of the SiNx layer, ensuring proper display functionality.

The use of ITO in the black metal layer stack may create a fully conductive structure. This may improve the electrical connection between the black metal layers and the common electrode.

Some implementations may reduce the resistance of the common electrode by using ITO as a conductive layer in the black metal stack. In the CVD process, the Mo layers in the black metal stack may be separated by SiNx layers, increasing the resistance of the common electrode. The use of ITO in the PVD process may allow for better electrical connectivity and reduced electrical resistance.

Some implementations may address issues with polyimide (PI) layer coverage and uniformity. Black metal formed from four layers in the CVD process may have three to four times the thickness of a single metal light shield layer, creating steep edges with high taper angles. The PVD process may reduce the taper angle of the black metal stack, improving PI coverage and uniformity, wherein uniformity is thickness across the layer.

Some implementations may achieve low reflectivity by designing the black metal stack for multilayer destructive interference. Designs based on Mo, ITO, and silicon dioxide (SiO₂) may be proposed for low reflectivity and low transmission thin films. The refractive index of ITO may be similar to SiNx, allowing for effective destructive interference without significant changes to the layer thickness.

Some implementations may allow for the use of alternative transparent conductor materials in place of ITO, such as tin oxide (SnO₂) or zinc oxide (ZnO). These materials may be used as substitutes for layers one and three in the black metal stack and may be different materials.

The process flow for the black metal stack with ITO may include depositing the first Mo layer, depositing the first ITO layer, depositing the second Mo layer, depositing the second ITO layer, performing lithography, etching the second ITO layer, etching the second Mo layer, etching the first ITO layer, and etching the first Mo layer. Alternatively, the common electrode ITO layer may replace the last ITO layer in the black metal stack. In this case, the process flow may include depositing the first Mo layer, depositing the first ITO layer, depositing the second Mo layer, and depositing the common electrode ITO layer as the second ITO layer.

Some implementations may include a reverse order process where an ITO layer is added underneath the black metal stack as an etch stopper. This ITO layer may be a sacrificial layer or act as a functional common electrode layer. The process flow for this approach may include depositing the ITO layer, depositing the first Mo layer, etching the first Mo layer, depositing the first SiNx layer, depositing the second Mo layer, etching the second Mo layer, depositing the second SiNx layer, performing lithography, etching the SiNx/Mo/SiNx/Mo layers, and etching the ITO layer. Alternatively, the process flow may include depositing the ITO layer, patterning the ITO layer, depositing the first Mo layer, etching the first Mo layer, depositing the first SiNx layer, depositing the second Mo layer, etching the second Mo layer, depositing the second SiNx layer, performing lithography, and etching the SiNx/Mo/SiNx/Mo layers.

Some implementations may account for the potential crystallization of ITO due to high process temperatures in the black metal stack. Crystallized ITO may be difficult to pattern and remove, so the etching sequence may be carefully designed.

If the refractive index of the replacement material, such as ITO, differs from SiNx, the layer thicknesses may be adjusted to maintain destructive interference for reflectivity reduction. Further with respect to two successive layers, the relationship between the two refractive indexes can be characterized as similar when the refractive index difference is less than 15%. For example, layer 1 comprising a refractive index of 1.5 and layer 2 comprising a refractive index of 1.8 can be characterized as having dissimilar refractive indexes due to their respective difference in value being greater than 15%.

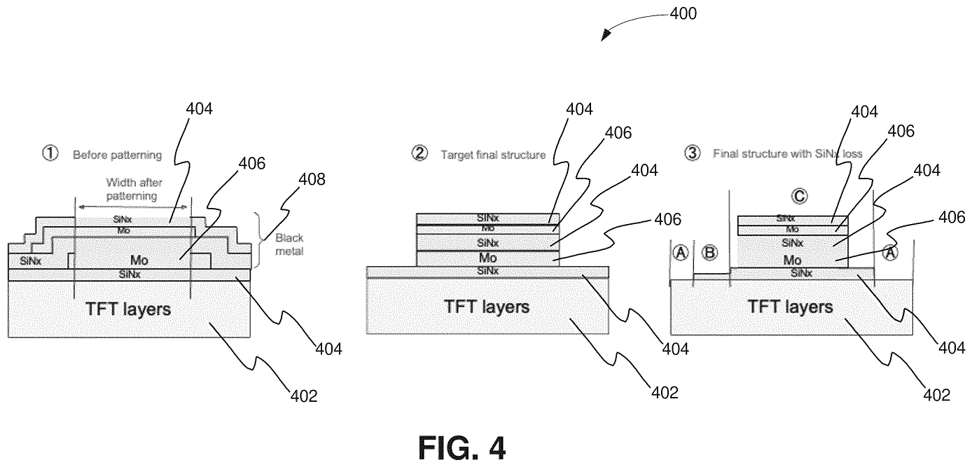

FIG. 4 illustrates a layer stack diagram 400 which supports techniques for conductive metals for mixed reality liquid crystal display devices in accordance with various aspects of the present disclosure. As depicted in FIG. 4, the layer stack diagram 400 may include one or more of TFT layers 402, SiNx layers 404, Mo layers 406, black metal 408, and/or other components.

The TFT layers 402 may include various thin-film transistors. The TFT layers 402 may be used to control the individual pixels in the display. The TFT layers 402 may be fabricated using semiconductor materials such as amorphous silicon or polysilicon. The TFT layers 402 may be integrated with other layers in the display panel to form the complete pixel structure. In some implementations, the TFT layers 402 may be arranged in a matrix configuration to address each pixel independently.

The SiNx layers 404 may represent a silicon nitride layer. The SiNx layers 404 may be used as an insulating layer in the display panel. The SiNx layers 404 may be deposited using a Chemical Vapor Deposition (CVD) process. The SiNx layers 404 may serve as a barrier to protect underlying layers from contamination. In some implementations, the SiNx layers 404 may be used in combination with other dielectric materials to enhance the overall performance of the display.

The Mo layers 406 may include a molybdenum layer. The Mo layers 406 may be used as a conductive layer in the display panel. The Mo layers 406 may be deposited using a Physical Vapor Deposition (PVD) process. The Mo layers 406 may be patterned to form electrical connections between different components of the display. In some implementations, the Mo layers 406 may be used in a multilayer stack to achieve specific electrical and optical properties.

The black metal 408 may represent a multilayer black metal structure. The black metal 408 may be used to reduce off-axis color mixing and act as a light-shielding layer. The black metal 408 may be composed of alternating layers of molybdenum and silicon nitride. The black metal 408 may be deposited using a combination of CVD and PVD processes. In some implementations, the black metal 408 may be designed to achieve low reflectance through multilayer destructive interference.

In some implementations, the TFT layers 402 may serve as the foundational structure upon which the subsequent layers are deposited. An initial SiNx layer 404 may be positioned directly above the TFT layers 402 and may act as a dielectric layer within the stack. An initial Mo layer 406 may be deposited above the initial SiNx layer 404 and may function as a conductive layer within the black metal stack. The black metal 408 may consist of multiple layers, including alternating SiNx layers 404 and Mo 406 layers, and may be situated above the initial SiNx layer 404.

In some implementations, the components may operate together such that the SiNx layer 404 may act as an etch stopper during the patterning of the Mo layer 406, while the Mo layer 406 may provide electrical conductivity within the stack. The black metal 408 may reduce reflectance through its multilayer structure, which may include alternating SiNx layers 404 and Mo 406 layers.

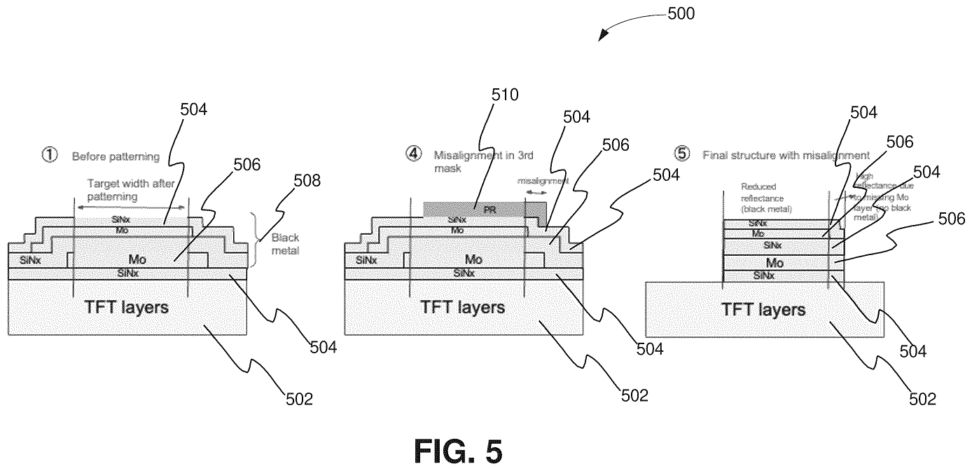

FIG. 5 illustrates a misalignment 500 which supports techniques for conductive metals for mixed reality liquid crystal display devices in accordance with various aspects of the present disclosure. As depicted in FIG. 5, the misalignment 500 causing issues may include one or more of TFT layers 502, SiNx layers 504, Mo layers 506, a black metal 508, a photoresist (PR) layer 510, and/or other components.

The TFT layers 502 may include various thin-film transistors. In some implementations, the TFT layers 502 may be the same as or similar to the TFT layers 402, as described herein. The SiNx layers 504 may represent silicon nitride layers. In some implementations, the SiNx layers 504 may be the same as or similar to the SiNx layers 404, as described herein. The Mo layers 506 may include molybdenum layers. In some implementations, the Mo layers 506 may be the same as or similar to the Mo layers 406, as described herein. The black metal 508 may represent a multilayer black metal structure. In some implementations, the black metal 508 may be the same as or similar to the black metal 408, as described herein.

The PR 510 may include a photoresist layer. The PR 510 may be used in the lithography process to pattern the underlying layers. The PR 510 may be applied to the surface of the substrate and then exposed to light to create a pattern. The PR 510 may be removed after the patterning process is complete. The PR 510 layer may be applied as a photoresist during the lithography process and may define the patterning of the black metal 508 and underlying layers.

One potential result of mask misalignment is illustrated in FIG. 5 where the PR 510 is shown beyond the target width indicated, which may yield a final structure that is also outside of the target width. This misalignment can cause high reflectance due to a missing Mo layer 506.

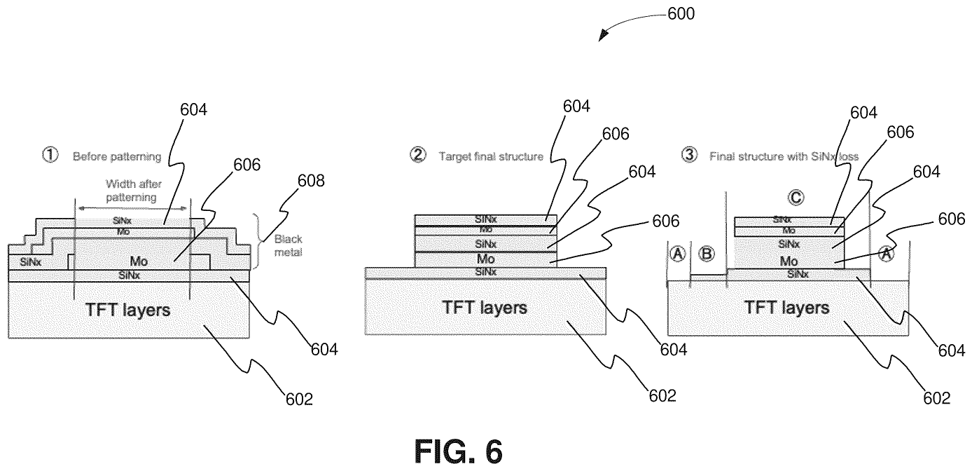

FIG. 6 illustrates silicon nitride loss 600 which supports techniques for conductive metals for mixed reality liquid crystal display devices in accordance with various aspects of the present disclosure. As depicted in FIG. 6, the layer stack diagram 600 may include one or more of TFT layers 602, SiNx layers 604, Mo layers 606, a black metal 608, and/or other components.

The TFT layers 602 may include various thin-film transistors. In some implementations, the TFT layers 602 may be the same as or similar to the TFT layers 402 and/or TFT layers 502, as described herein. The SiNx layers 604 may represent a silicon nitride layer. In some implementations, the SiNx layer 604 may be the same as or similar to the SiNx layer 404 and/or SiNx layer 504, as described herein. The Mo layers 606 may include a molybdenum layer. In some implementations, the Mo layer 606 may be the same as or similar to the Mo layer 406 and/or Mo layer 506, as described herein. The black metal 608 may represent a multilayer black metal structure. In some implementations, the black metal 608 may be the same as or similar to the black metal 408 and/or black metal 508, as described herein.

The region A may indicate a region with complete loss of the underlying SiNx layer. The region A may be a critical area where the SiNx layer has been entirely etched away. The complete loss of the SiNx layer in the region A may result in significant performance issues for the display. In some implementations, the region A may be adjacent to regions with partial or minimal etching, such as the region B and region C.

The region B may indicate a region with partial etching of the underlying SiNx layer. The region B may be characterized by significant but not complete removal of the SiNx layer. This partial etching in the region B may lead to non-uniform electrical and optical properties. In some implementations, the region B may be located between regions with complete loss and minimal etching, such as the region A and region C.

The region C may indicate a region with minimal or no etching of the underlying SiNx layer. The region C may retain most or all of the original SiNx layer, maintaining its intended properties. Minimal or no etching in the region C may ensure consistent performance in those areas. In some implementations, the region C may be found adjacent to regions with more significant etching, such as the region A and region B.

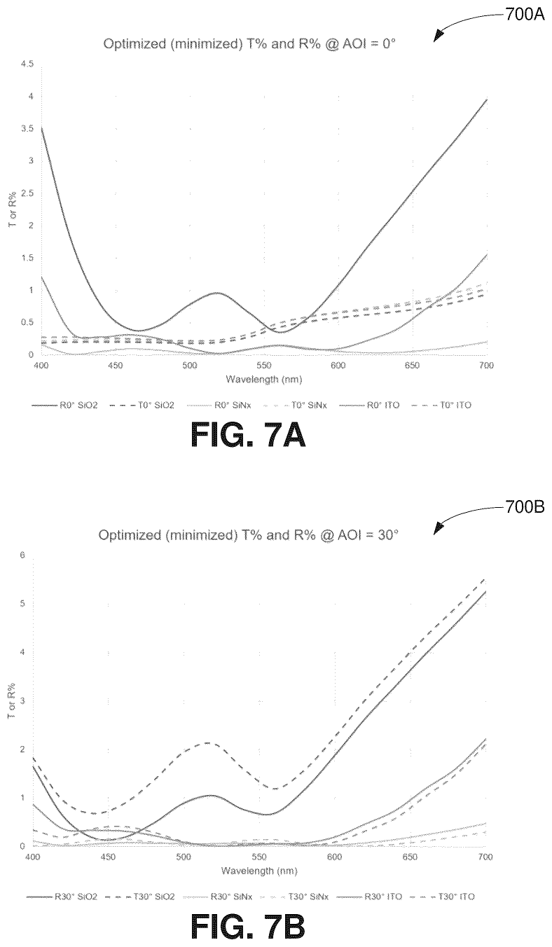

FIGS. 7A and 7B show line graphs 700A and 700B, respectively, illustrating the optimized (minimized) transmission (T%) and reflectivity (R%), in accordance with various aspects of the present disclosure. The line graph 700A shows data at an angle of incidence (AOI) of 0° across a range of wavelengths, and the line graph 700B shows data at an angle of incidence (AOI) of 0° across a range of wavelengths. The line graphs 700A and 700B may represent the optical performance of different material layer stacks, including SiO₂, SiNx, and ITO, as part of a thin-film structure.

The horizontal axis of the line graphs 700A and 700B may represent the wavelength of light in nanometers (nm), ranging from 400nm to 700nm. The vertical axis may represent the percentage values of transmission (T%) and reflectivity (R%), ranging from 0% to 4.5%. Both axes may use a linear scale.

The line graphs 700A and 700B may include multiple data sets, each represented by distinct line styles. Solid lines may indicate reflectivity (R%) for the respective materials, while dashed lines may indicate transmission (T%).

The data points in the line graphs 700A and 700B may show trends in optical performance for each material. For SiO₂, the reflectivity (R%) may exhibit a peak near 400 nm and gradually decrease before rising again at longer wavelengths. The transmission (T%) for SiO₂ may follow a complementary trend, with a minimum near 400 nm and a gradual increase across the wavelength range.

For SiNx, the reflectivity (R%) may remain relatively low and stable across the wavelength range, while the transmission (T%) may also exhibit minimal variation, maintaining a consistent trend. These characteristics may indicate the optical stability of SiNx in the thin-film structure.

For ITO, the reflectivity (R%) may show a slight increase at longer wavelengths, while the transmission (T%) may remain relatively low and stable. These trends may suggest that ITO provides a balance of optical properties suitable for minimizing reflectivity and transmission in the thin-film stack.

The line graphs 700A and 700B may highlight notable features, such as the valleys in reflectivity and transmission curves, which may correspond to optimized destructive interference conditions. These features may be critical for achieving low reflectivity and low transmission in the thin-film structure.

The line graphs 700A and 700B may collectively demonstrate the comparative optical performance of SiO₂, SiNx, and ITO, providing insights into their suitability for specific applications. The graph may also suggest that alternative transparent conductive materials, such as SnOx or ZnO, could exhibit similar trends if used in place of ITO, with adjustments to layer thicknesses to account for differences in refractive indices.

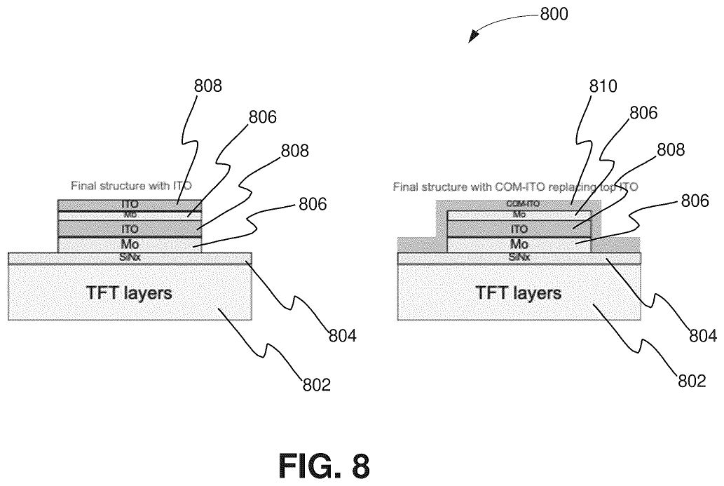

FIG. 8 illustrates layer stack comparison 800 which supports techniques for conductive metals for mixed reality liquid crystal display devices in accordance with various aspects of the present disclosure. As depicted in FIG. 8, the layer stack comparison 800 may include one or more of TFT layers 802, SiNx layers 804, Mo layers 806, ITO layers 808, COM ITO layers 810, and/or other components.

The TFT layers 802 may include various thin-film transistors. In some implementations, the TFT layers 802 may be the same as or similar to the TFT layers 402, TFT layers 502, and/or TFT layers 602, as described herein. The SiNx layers 804 may represent a silicon nitride layer. In some implementations, the SiNx layers 804 may be the same as or similar to the SiNx layers 404, SiNx layers 504, and/or SiNx layers 604, as described herein. The Mo layers 806 may include a molybdenum layer. In some implementations, the Mo layers 806 may be the same as or similar to the Mo layers 406, Mo layers 506, and/or Mo layers 606, as described herein. The ITO layers 808 may represent an indium tin oxide layer. The COM ITO 810 may include a common indium tin oxide layer. The benefit of the embodiment is defined by the layers of Mo layers 806 and ITO layers 808, wherein the ITO layers 808 replaces the SiNx layer 604, 504 between the Mo layers 806. ITO layer 808 allows the black metal variant to maintain an electrical connection between the two Mo Layers 806 due to the electroconductive properties of the ITO. Further, the arrangement of layers in FIG. 8 facilitates better control of the liquid crystal. For example, the direct connection between the COM ITO layer 810 or ITO layer 808 reduces the resistance with the liquid crystal layer adjacent (not shown) to the COM ITO layer 810 or ITO layer 808. The reduced resistance can reduce a potential display flicker response and the overall response will be quicker.

In some implementations, the TFT layers 802 may serve as the foundational structure upon which the subsequent layers are deposited. The SiNx layer 804 may be positioned directly above the TFT layers 802 and may act as a dielectric layer separating the conductive layers. The first Mo layer 806 may be deposited on top of the SiNx layer 804, followed by the first ITO layer 808, which may serve as an etch stopper or conductive layer. The second Mo layer 806 may then be deposited above the first ITO layer 808, and the COM ITO layer 810 may be positioned as the topmost layer in the stack. On an exemplary embodiment for FIG. 8, the first layer comprising ITO (e.g., layer 808 or 810) can comprise a thickness of approximately 58.6 nm, the second Mo Layer 806 can comprise a thickness of approximately 5.76 nm, the third layer (second layer of ITO 808) can comprise a thickness of approximately 55.94 nm, and the fourth layer (second Mo layer 806) can comprise a thickness of approximately 50 nm. The relative thickness of the second Mo layer 806 at about 5.76 nm is exemplary in that the second Mo layer can also exhibit transparency in while also providing a refractive index mismatch to the two ITO layers 808. In other embodiments, the second metal layers can be deposited with a similar decreased thickness to exhibit desired properties of transparency, refractive index, and electrical conductivity.

In some implementations, the COM ITO layer 810 may extend laterally beyond the underlying layers, as shown in the image, which may influence the taper angle of the stack. The Mo layers 806 and ITO layers 808 may interact during the etching process, where the ITO layers 808 may act as etch stoppers to prevent over etching of the SiNx layer 804. The arrangement of the layers may allow for precise patterning during lithography, as the ITO layers 808 and COM ITO layer 810 may exhibit good etch selectivity against the Mo layers 806 and SiNx layer 804.

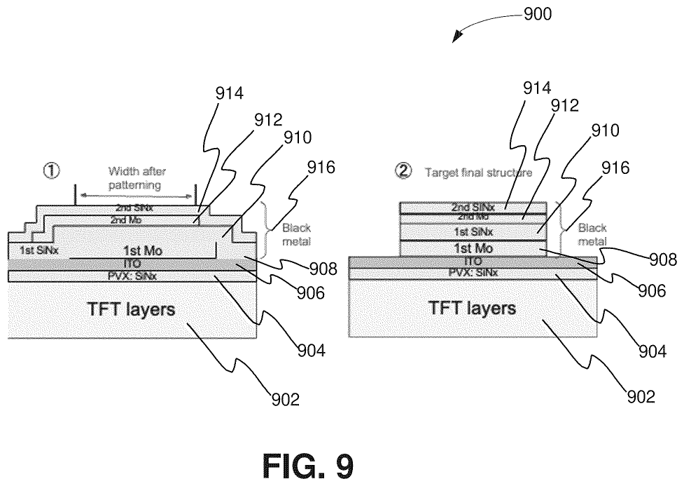

FIG. 9 illustrates layer structure comparison 900 which supports techniques for conductive metals for mixed reality liquid crystal display devices in accordance with various aspects of the present disclosure. As depicted in FIG. 9, the layer structure comparison 900 may include one or more of TFT layers 902, a physical-vapor deposited silicon nitride (PVX-SiNx) PVX-SiNx layer 904, an ITO layer 906, a first Mo layer 908, a first SiNx layer 910, a second Mo layer 912, a second SiNx layer 914, black metal 916, and/or other components. In one aspect, the embodiment of FIG. 9 can be configured to reduce the over-etching of the underlying PVX-SiNx layer 904.

The TFT layers 902 may include various thin-film transistors. In some implementations, the TFT layers 902 may be the same as or similar to the TFT layers 402, TFT layers 502, TFT layers 602, and/or TFT layers 802, as described herein. The PVX-SiNx layer 904 may represent a silicon nitride layer critical for pixel operation. This layer may be used as part of a storage capacitor in the display panel. The PVX-SiNx layer 904 may be deposited using a Physical Vapor Deposition (PVD) process. In some implementations, the PVX-SiNx layer 904 may be similar to the SiNx layer 404, SiNx layer 504, SiNx layer 604, and/or SiNx layer 804, as described herein. The ITO layer 906 may include indium tin oxide used as an etch stopper. The first Mo layer 908 may include the first layer of molybdenum. In some implementations, the first Mo layer 908 may be the same as or similar to Mo layer 406, Mo layer 506, Mo layer 606, and/or layer Mo 806, as described herein.

The first SiNx layer 910 may include the first silicon nitride layer. This layer may be deposited on top of the first Mo layer 908. The first SiNx layer 910 may be used to provide insulation between the first Mo layer 908 and the second Mo layer 912. In some implementations, the first SiNx layer 910 may be similar to the SiNx layer 404, SiNx layer 504, SiNx layer 604, and/or SiNx layer 804, as described herein. The second Mo layer 912 may include the second layer of molybdenum. In some implementations, the second Mo layer 912 may be the same as or similar to the Mo layer 406, Mo layer 506, Mo layer 606, and/or Mo layer 806, as described herein. The second SiNx layer 914 may include the second silicon nitride layer. This layer may be deposited on top of the second Mo layer 912. The second SiNx layer 914 may be used to provide insulation between the second Mo layer 912 and the black metal 916. In some implementations, the second SiNx layer 914 may be similar to the SiNx layer 404, SiNx layer 504, SiNx layer 604, and/or SiNx layer 804, as described herein.

The black metal 916 may include a multilayer structure for reducing reflectivity. In some implementations, the black metal 916 may be the same as or similar to the black metal 408, black metal 508, and/or black metal 608, as described herein.

In some implementations, the TFT layers 902 may serve as the foundational structure upon which the subsequent layers are deposited. The PVX-SiNx layer 904 may be positioned directly above the TFT layers 902, acting as a dielectric layer. The ITO layer 906 may be deposited on top of the PVX-SiNx layer 904, forming a conductive layer that interfaces with the black metal stack. The first Mo layer 908 may be layered above the ITO layer 906, followed by the first SiNx layer 910, which may act as an insulating layer between the first Mo layer 908 and the subsequent layers.

In some implementations, the second Mo layer 912 may be deposited above the first SiNx layer 910, creating a second conductive layer within the stack. The second SiNx layer 914 may then be deposited above the second Mo layer 912, completing the multilayer structure. The black metal 916 may encompass the first Mo layer 908, first SiNx layer 910, second Mo layer 912, and second SiNx layer 914, forming a composite layer that may function as a light-shielding element. These components may operate together to achieve the desired multilayer interference effects, with the ITO layer 906 potentially serving as an etch stopper during the patterning and etching processes.

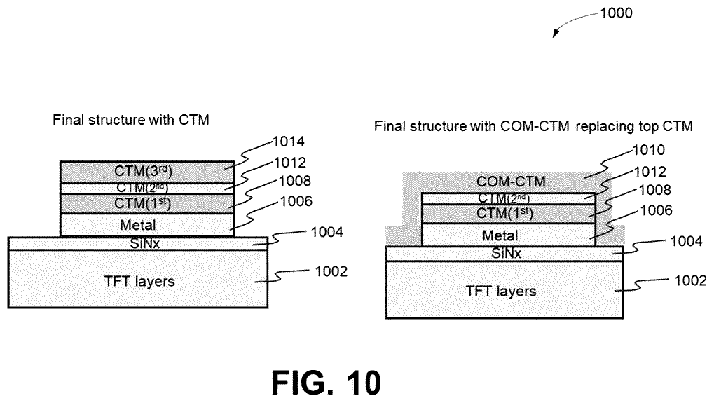

For all of the embodiments previously discuss and depicted in figures, a generalized black metal structure can comprise a stack of layers as depicted in FIG. 10. As depicted in FIG. 10, the layer stack comparison 1000 may include one or more of TFT layers 1002, SiNx layers 1004, metal layer 1006, conductive and transparent material (CTM) layers 1008, 1012, 1014, COM-CTM layer 1010, and/or other components.

The TFT layers 1002 may include various thin-film transistors. In some implementations, the TFT layers 1002 may be the same as or similar to the TFT layers 402, TFT layers 502, TFT layers 602, and/or the TFT layers 802 as described herein. The SiNx layers 1004 may represent a silicon nitride layer. In some implementations, the SiNx layers 1004 may be the same as or similar to the SiNx layers 404, SiNx layers 504, SiNx layers 604, and/or SiNx layers 804 as described herein. In some implementations, the metal layers 1006 may be the same as or similar to the Mo layers 406, Mo layers 506, Mo layers 606, and/or Mo layers 806 as described herein. The metal layers 1006 may include: Molybdenum (Mo), Titanium (Ti), Molybdenum Tungsten (MoW) or Tungsten (W). The conductive and transparent material layers 1008 are configured to exhibit desired properties of transparency, refractive index, and electrical conductivity. The conductive and transparent material layer can comprise one of: Indium tin oxide (ITO), Tin Oxide (SnOx), Indium Zinc Oxide (IZO), Indium tin zinc oxide (ITZO), Zinc oxide (ZnO), and doped Zinc Sulfide (ZnS).

In some implementations, the TFT layers 1002 may serve as the foundational structure upon which the subsequent layers are deposited. The SiNx layer 1004 may be positioned directly above the TFT layers 1002 and may act as a dielectric layer separating the conductive layers. The metal layer 1006 may be deposited on top of the SiNx layer 1004, followed by the first conductive and transparent material (CTM) layer 1008. The second conductive and transparent material layers 1012 may then be deposited above the first conductive and transparent material layer 1008. The third conductive and transparent material layer 1014 may then be deposited above the second conductive and transparent material layer 1012. COM-CTM layer 1010 may be positioned as the topmost layer in the stack 1000. For example, alternate embodiments can comprise an excess of conductive and transparent material layers, wherein the COM-CTM layer 1010 can still be positioned as the topmost layer. The direct connection between the COM-CTM layer 1010 or CTM layer 1008 reduces the resistance with the liquid crystal layer adjacent (not shown) to the COM-CTM layer 1010 or CTM layer 1008. The reduced resistance can reduce a potential display flicker response and the overall response will be quicker.

In a further aspect, between each respective conductive and transparent material layer, there can be a mismatch in refractive index. For example: there can be a first refractive index mismatch between the metal layer 1006 and the first conductive and transparent material layer 1008. There can be a second refractive index mismatch between the first conductive and transparent material layer 1008 and the second conductive and transparent material layer 1012. There can be a third refractive index mismatch between the second conductive and transparent material layer 1012 and the third conductive and transparent material layer 1014. The mismatch in refractive index indicates that the difference between refractive indexes of respective layers will exhibit a difference in reflection and refraction patterns for the layers of that particular mismatch. In order to facilitate the mismatch in refractive index, the thickness of the layers 1006, 1008, 1012, 1014 can be adjusted. The layers in the generalized embodiment in FIG. 10 can comprise a metal layer 1006 and plurality of successive conductive and transparent material layers 1008, 1012, 1014. One of the plurality of successive conductive and transparent material layers can comprise a metal, wherein the thickness of at least one of the conductive and transparent material layers permits the metal to exhibit transparency. For example, similar to the second Mo layer in FIG. 8, the second conductive and transparent material layer 1012 can comprise a metal with a decreased thickness (e.g., 5.76 nm) such that the second conductive and transparent material layer 1012 can function both as a metal and provide transparency.

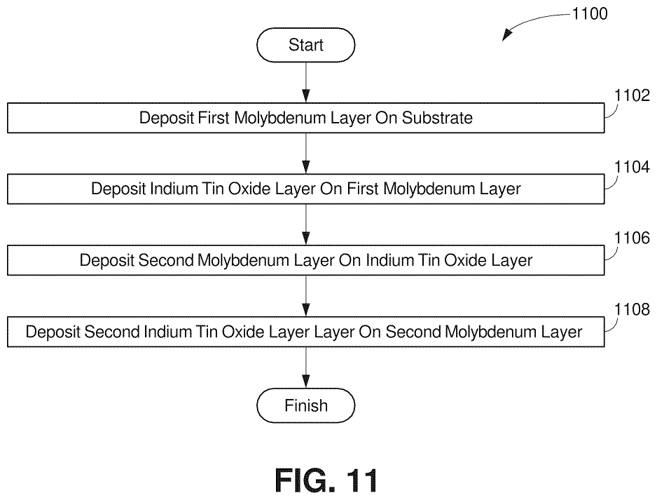

FIG. 11 illustrates a flowchart illustrating a method 1100 of manufacturing structures in accordance with various aspects of the present disclosure. At step 1102, the method 1100 may include depositing a first molybdenum layer on a substrate. The operations of step 1102 may be performed in accordance with examples as disclosed herein. At step 1104, the method 1100 may include depositing an ITO layer on the first molybdenum layer. The operations of 1104 may be performed in accordance with examples as disclosed herein. At step 1106, the method 1100 may include depositing a second molybdenum layer on the ITO layer. The operations of step 1106 may be performed in accordance with examples as disclosed herein. At step 1108, the method 1100 may include depositing a second ITO layer on the second molybdenum layer. The operations of step 1108 may be performed in accordance with examples as disclosed herein.

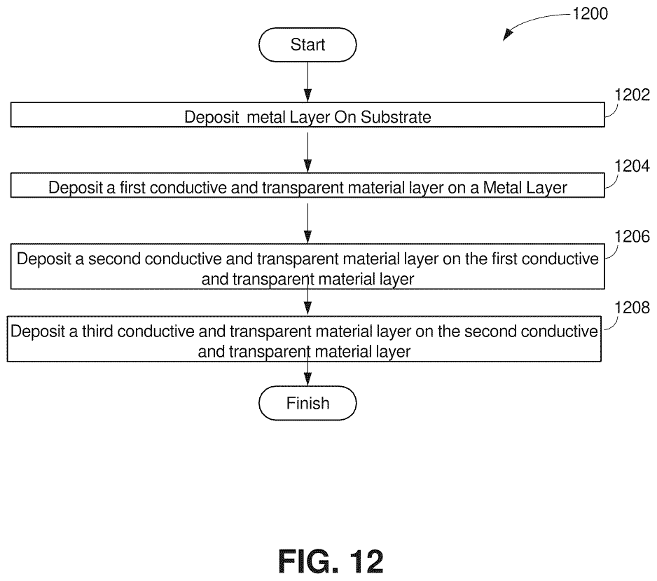

FIG. 12 illustrates a flowchart illustrating a method 1200 of manufacturing structures in accordance with various aspects of the present disclosure. At step 1202, the method 1200 may include depositing a metal layer on a substrate. The operations of step 1202 may be performed in accordance with examples as disclosed herein. At step 1204, the method 1200 may include depositing a first conductive and transparent material layer on a metal layer. The operations of 1204 may be performed in accordance with examples as disclosed herein. At step 1206, the method 1200 may include depositing a second conductive and transparent material layer on the first conductive and transparent material layer. At step 1208, the method 1200 may include depositing a third conductive and transparent material layer on the second conductive and transparent material layer.

It should be noted that the methods described herein describe possible implementations, and that the operations and the steps may be rearranged or otherwise modified and that other implementations are possible. Furthermore, aspects from two or more of the methods may be combined.

The disclosed system(s) address a problem in traditional electronic display techniques, namely, the technical problem of high reflectance and inefficiency in black metal layers for mixed reality LCD displays. The disclosed technologies and related methods solve this technical problem by providing a solution, namely, by providing for conductive metals for mixed reality liquid crystal display devices.

As used herein, the phrase “at least one of” preceding a series of items, with the terms “and” or “or” to separate any of the items, modifies the list as a whole, rather than each member of the list (i.e., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

To the extent that the terms “include,” “have,” or the like is used in the description or the claims, such term is intended to be inclusive in a manner similar to the term “comprise” as “comprise” is interpreted when employed as a transitional word in a claim. The word “exemplary” is used herein to mean “serving as an example, instance, or illustration.” Any embodiment described herein as “exemplary” is not necessarily to be construed as preferred or advantageous over other embodiments.

A reference to an element in the singular is not intended to mean “one and only one” unless specifically stated, but rather “one or more.” All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed to achieve desirable results. The actions recited in the claims can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products. Other variations are within the scope of the following claims.

What is claimed is:

1. A black metal structure, comprising:
a first molybdenum layer deposited on a substrate;
an indium tin oxide (ITO) layer deposited on the first molybdenum layer;
a second molybdenum layer deposited on the ITO layer; and
a second ITO layer deposited on the second molybdenum layer.

2. The black metal structure of claim 1, further comprising a physical-vapor deposited silicon nitride (PVX-SiNx) layer deposited on the substrate.

3. The black metal structure of claim 1, wherein the ITO layer and the second ITO layer are deposited in response to a physical vapor deposition process.

4. The black metal structure of claim 1, wherein the first molybdenum layer and the second molybdenum layer are patterned to achieve a target final structure.

5. The black metal structure of claim 1, wherein the ITO layer and the second ITO layer have a similar refractive index to silicon nitride (SiNx).

6. The black metal structure of claim 1, wherein the ITO layer and the second ITO layer are configured to act as an etch stopper for molybdenum.

7. The black metal structure of claim 1, wherein the ITO layer and the second ITO layer exhibit etch selectivity against SiNx.

8. The black metal structure of claim 1, wherein the ITO layer and the second ITO layer are configured to reduce electrical resistance of a COM ITO.

9. The black metal structure of claim 1, wherein the ITO layer and the second ITO layer are configured to provide a conductive black metal stack.

10. The black metal structure of claim 1, wherein the ITO layer and the second ITO layer are configured to replace SiNx without a significant change to a thickness dimension of the black metal.

11. A black metal structure, comprising:
a metal layer deposited on a substrate;
a first conductive and transparent material layer deposited on the metal layer;
a second conductive and transparent material layer deposited on the first conductive and transparent material layer; and
a third conductive and transparent material layer deposited on the second conductive and transparent material layer.

12. The black metal structure of claim 11, wherein:
a first refractive index mismatch between the metal layer and the first conductive and transparent material layer;
a second refractive index mismatch between the first conductive and transparent material layer and the second conductive and transparent material layer; and
a third refractive index mismatch between the second conductive and transparent material layer and the third conductive and transparent material layer.

13. The black metal structure of claim 11, further comprising at least one additional conductive and transparent material layer deposited on the third conductive and transparent material layer, wherein there is a fourth refractive index mismatch between the third conductive and transparent material layer and at least one additional conductive and transparent material layer.

14. The black metal structure of claim 11 wherein the metal layer comprises one of: Molybdenum (Mo), Titanium (Ti), Molybdenum Tungsten (MoW), Tungsten (W), or Chromium (Cr); and any of the conductive and transparent material layer comprise one of: Indium tin oxide (ITO), Tin Oxide (SnOx), Indium Zinc Oxide (IZO), Indium tin zinc oxide (ITZO), Zinc oxide (ZnO), and doped Zinc Sulfide (ZnS).

15. The black metal structure of claim 14 wherein at least one of the conductive and transparent material layers includes a metal similar to the metal layer, wherein the thickness of at least one of the conductive and transparent material layers permits the metal to exhibit transparency.

16. A method of manufacturing a black metal structure, comprising:
depositing a first molybdenum layer on a substrate;
depositing an indium tin oxide (ITO) layer on the first molybdenum layer;
depositing a second molybdenum layer on the ITO layer; and
depositing a second ITO layer on the second molybdenum layer.

17. The method of manufacturing a black metal structure of claim 16, further comprising depositing a physical-vapor deposited silicon nitride (PVX-SiNx) layer on the substrate.

18. The method of manufacturing a black metal structure of claim 16, wherein the ITO layer and the second ITO layer are deposited in response to a physical vapor deposition process.

19. The method of manufacturing a black metal structure of claim 16, wherein the first molybdenum layer and the second molybdenum layer are patterned to achieve a target final structure.

20. The method of manufacturing a black metal structure of claim 16, wherein the ITO layer and the second ITO layer have a similar refractive index to silicon nitride (SiNx).
